(19) United States
(12) Patent Application Publication
(10) Pub. No.: US 2010/0278287 A1
(43) Pub. Date: Nov. 4, 2010

(54) List Output Viterbi Deconder with Blockwise ACS and Traceback

(75) Inventors: Roy Skovgaard Hansen, Dragoer (DK); Peter Bjoern-Joergensen, Roskilde (DK)

Correspondence Address: BANNER & WITCOFF, LTD., 1100 13th STREET, N.W., SUITE 1200, WASHINGTON, DC, 20005-4051, US

(73) Assignee: NOKIA CORPORATION, Espoo (FI)

(21) Appl. No.: 10/550,094

(22) PCT Filed: Mar. 27, 2003
(86) PCT No.: PCT/EP03/03179

§ 371 Date: Feb. 14, 2008

(51) Int. Cl. H03D 1/00

(52) U.S. Cl. 375/341

(57) ABSTRACT

A Viterbi decoder for decoding convolution-coded data blocks has a memory region (314) used for the decision matrix. This memory region is too small to hold all of the decisions for one data block. Instead, the decision matrix is repopulated for different sections of the data block during the decoding process. When a list Viterbi algorithm is employed, the modified tracebacks can be limited to data block sections containing bad decisions and preceding sections.

### FIELD OF THE INVENTION

The present invention relates to a Viterbi decoder and a Viterbi decoding method.

### BACKGROUND TO THE INVENTION

Viterbi decoders are well-known and widely used in the field of communications. Viterbi decoders are used to decode continuous convolution-coded bitstreams and discrete convolution-coded data blocks.

When Viterbi decoding is applied to convolution-coded data block, a decision matrix representing all paths that survive through the whole block is generated and, typically, stored in a RAM. Taking the example of EGPRS decoding, in which each block comprises 612 symbols, the memory required for decoding one block is 47 764 bits. This consists of 39 168 decision matrix bits, 7 344 input bits which comprise 12 (3×4) soft bits for each symbol, 640 cumulative metric bits and 612 output bits. It can be seen that the decision matrix bits represent 82% of the total memory requirement. Consequently, any significant reduction in the size of the decision matrix results in a significant reduction in the overall memory requirement.

### SUMMARY OF THE INVENTION

It is an aim of the present invention to provide a Viterbi decoder having a reduced memory requirement relative to conventional decoders.

According to the present invention, there is provided a Viterbi decoder for decoding convolution-coded data blocks, the decoder comprising a memory for storing a decision matrix and path metric processing means for populating the decision matrix in the memory with decision values on the basis of soft decision bits representing an input convolution-coded data block, characterised in that the number of elements of said memory, used for storing the decision matrix, is less than the product of the number of valid states for the input convolution-encoded data block and the number of symbols in the input convolution-encoded data block.

According to the present invention, there is also provided a Viterbi decoding method for decoding convolution-coded data blocks, the method comprising processing path metrics on the basis of input soft decision bits, representing an input convolution-coded data block, to populate a decision matrix in a memory with decision values, characterised in that the number of elements of said memory, used for storing the decision matrix, is less than the product of the number of valid states for the input convolution-encoded data block and the number of symbols in the input convolution-encoded data block.

Thus, since the decision matrix is split up into sections and the memory is reused, the amount of memory required is generally reduced, even allowing for a small increase in auxiliary information that may need to be stored.

Conveniently, said number is an integer sub-multiple of said product. However, it need not be. For instance, a decoder may be required to handle data blocks whose full decision matrices would require respectively 6 and 8.5 times the memory allocated for the storage of partial decision matrices according to the present invention.

Preferably, the path metric processing involves storing path metrics sets associated respectively with a plurality of spaced symbols in the input convolution-encoded data block and perform path metric processing for distinct sections of input convolution-coded data block using respective ones of said stored path metric sets as a starting state. This means that the decision matrix calculations do not always have to start from the beginning.

The path metric processing is preferably responsive to detection of an error in the decoded data, e.g. by means of a signal from error detection means, to regenerate a partial decision matrix including a bad decision and the traceback process is responsive to the detection of said error to modify the decoded data by tracing back a second best path through said partial decision matrix from said bad decision.

The path metric processing may be responsive to detection of an error in the decoded data to regenerate a first partial decision matrix including a bad decision and a second partial decision matrix for symbols immediately preceding those for which the first partial decision matrix was regenerated, and the traceback processing may be responsive to the detection of said error to modify the decoded data by tracing back a second best path through said first and second partial decision matrices from said bad decision.

Alternatively, said partial decision matrix covers a predetermined number of symbols preceding said bad decision to ensure that any non-best path traced with merge with the best path within the partial decision matrix.

### BRIEF DESCRIPTION OF THE DRAWINGS

FIG. 1 is a block diagram of a mobile phone;

FIG. 2 is a block diagram of a first Viterbi decoder according to the present invention;

FIG. 3 is a flowchart illustrating the operation of the Viterbi decoder of FIG. 2;

FIG. 4 is a block diagram of a second Viterbi decoder according to the present invention;

FIG. 5 is a more detailed block diagram showing in particular the metric processing circuit of the second Viterbi decoder;

FIG. 6 is a more detailed block diagram showing in particular the traceback circuit of the second Viterbi decoder;

FIG. 7 is a flowchart illustrating the operation of the Viterbi decoder of FIG. 4;

FIGS. 8(a) and 8(b) illustrate best and second best paths arising in different positions in partial decision matrices; and

FIG. 9 is a flowchart illustrating the operation of a third Viterbi decoder according to the present invention.

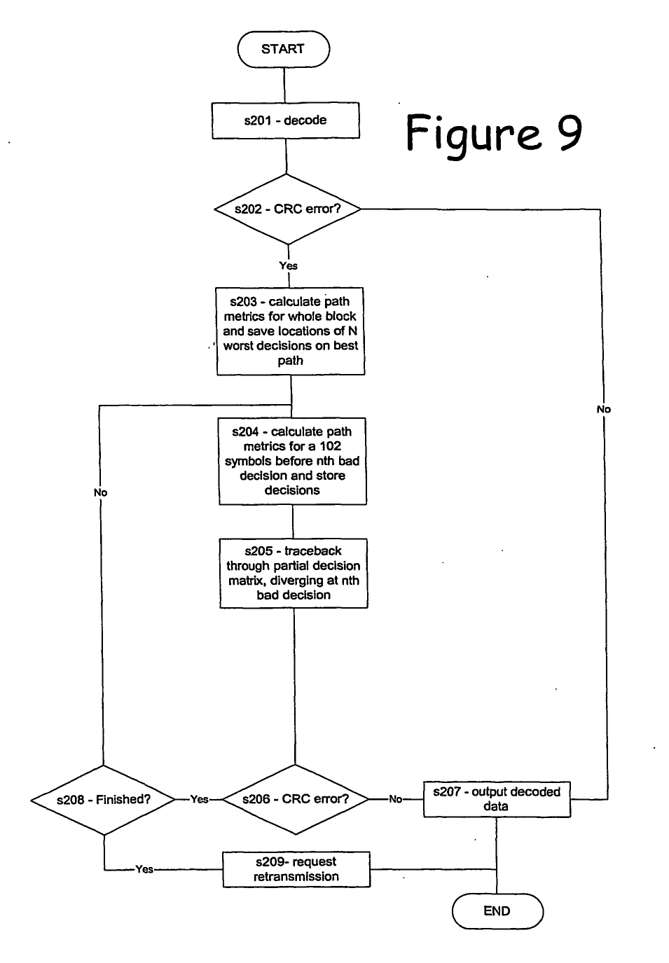

### DETAILED DESCRIPTION OF THE PREFERRED EMBODIMENTS

Embodiments of the present invention will now be described, by way of example, with reference to the accompanying drawings.

### First Embodiment

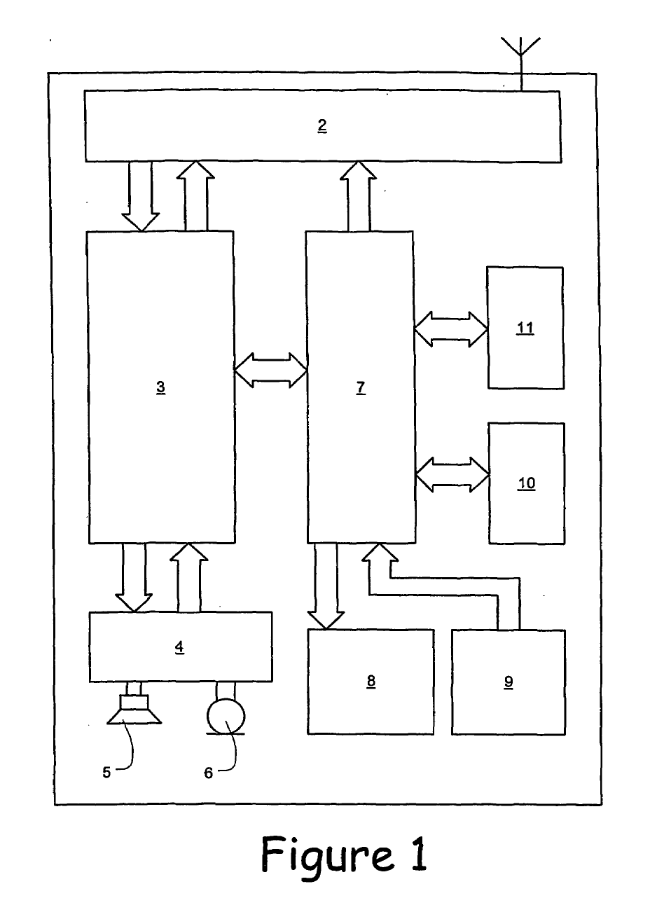

Referring to FIG. 1, the first mobile station comprises an antenna 1, an rf subsystem 2, a baseband DSP (digital signal processing) subsystem 3, an analogue audio subsystem 4, a loudspeaker 5, a microphone 6, a controller 7, a liquid crystal display 8, a keypad 9, memory 10 and a SIM card 11.

The rf subsystem 2 contains if and rf circuits of the mobile telephone's transmitter and receiver and a frequency synthesizer for tuning the mobile station's transmitter and receiver. The antenna 1 is coupled to the rf subsystem 2 for the reception and transmission of radio waves.

The baseband DSP subsystem 3 is coupled to the rf subsystem 2 to receive baseband signals therefrom and for sending baseband modulation signals thereto. The baseband DSP subsystems 3 includes codec functions which are generally well-known in the art. However, the codec functions include a novel Viterbi decoder, which is described in more detail below, for channel decoding. The output of the Viterbi decoder is then further decoded to regenerate the original speech signal in the case of telephony.

The analogue audio subsystem 4 is coupled to the baseband DSP subsystem 3 and receives demodulated audio therefrom. The analogue audio subsystem 4 amplifies the demodulated audio and applies it to the loudspeaker 5. Acoustic signals, detected by the microphone 6, are pre-amplified by the analogue audio subsystem 4 and sent to the baseband DSP subsystem 3 for coding.

The controller 7 controls the operation of the mobile telephone. It is coupled to the rf subsystem 2 for supplying tuning instructions to the frequency synthesizer and to the baseband DSP subsystem 3 for supplying control data and management data for transmission. The controller 7 operates according to a program stored in the memory 10. The memory 10 is shown separately from the controller 7. However, it may be integrated with the controller 7.

The display device 8 is connected to the controller 7 for receiving control data and the keypad 9 is connected to the controller 7 for supplying user input data signals thereto.

The controller 7 is programmed to control the mobile station for speech and data communication and with application programs, e.g. a WAP browser, which make use of the mobile station's data communication capabilities.

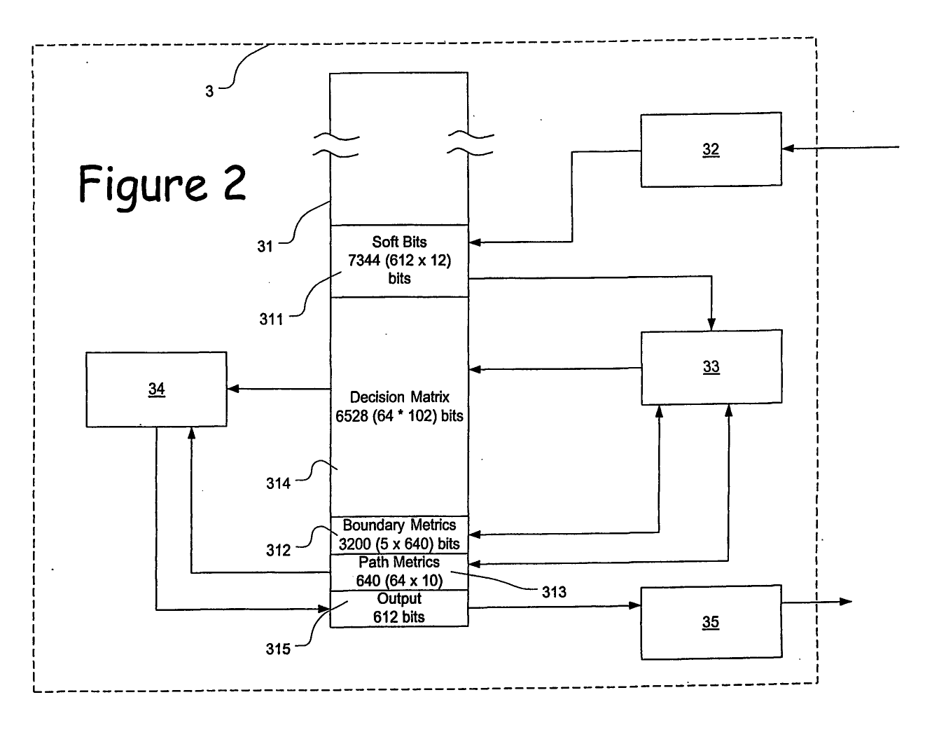

Referring to FIG. 2, the baseband DSP subsystem 3 includes a Viterbi decoder, comprising a random access memory (RAM) 31, a soft decision circuit 32, a metric processing circuit 33 and a traceback circuit 34, and additional signal processing circuits 35 which are not essential for understanding the present invention.

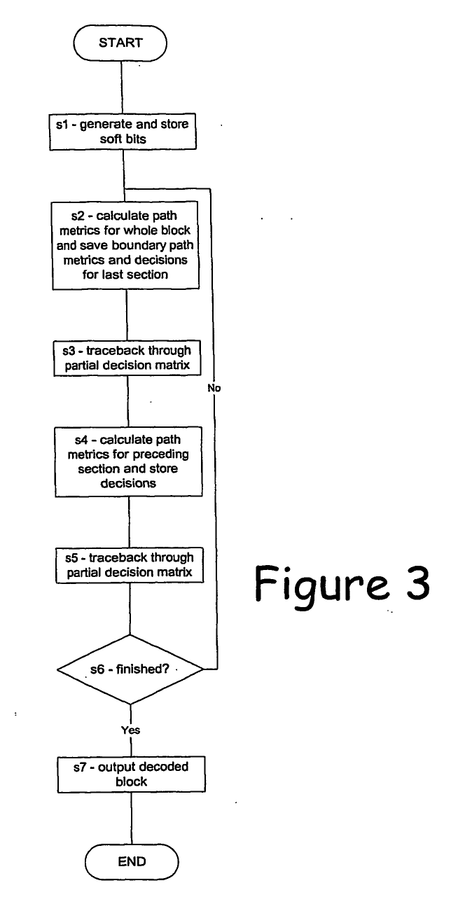

Referring additionally to FIG. 3, the soft decision circuit 32 receives blocks of 612 symbols from the rf subsystem 2 and outputs three 4-bit soft decisions for each input symbol, which are then stored in a part 311 of the RAM 31 reserved for soft bits (step s1). The soft bit part 311 has space for 7 344 bits.

When a block of soft decision bits has been stored in the soft bit part 311, the metric processing circuit 33 processes the soft decision bits to calculate path metrics (step s2). The calculated 10-bit path metrics for each trellis node at symbols 101, 203, 305, 407 and 509 (using a zero-based index) are stored in a boundary metric part 312 of the RAM 31. The path metrics for the surviving paths at the last symbol are stored in a path metric part 313 of the RAM. Additionally, the decisions for the final 102 symbols are stored in a 6528-bit decision matrix part 314 of the RAM 31.

When writing to the decision matrix part 314 is complete, the traceback circuit 34 begins its operation. The traceback circuit 34 traces the best path through the decision matrix and stores a 1-bit value for each symbol in respective locations of an output part 315 of the RAM 31 (step s3).

A process of partial metric calculation and traceback is now repeated for 102-symbol segments of the current block (step s6). If N is the number of 102-bit sections forming a block, i.e. six in the present example, and n is the current 102-bit section, the following is performed for n=N−1 down to 1.

The path metrics are calculated for the nth 102-bit sections (step s4). The nth set of path metrics stored in the boundary metrics part 312 of the RAM 31 are used as the starting point. The decisions are written to the decision matrix part 314 of the RAM, overwriting those previously stored and the final path metrics are written to the path metric part 313 of the RAM 31. Once the new decision matrix has been completed, the traceback circuit 11 traces the best path through the decision matrix, starting from the state and stores the next 102 1-bit symbol values in the output part 315 of the RAM 31 (step s5).

When all 612 1-bit symbol values have been obtained, they are read out of the output part 315 of the RAM 31 by the first processing circuit of the additional signal processing circuits 34 (step s7).

### Second Embodiment

The present embodiment differs from the first embodiment only in the operation of the Viterbi decoder, the general construction of the mobile phone begin as described above with reference to FIG. 1.

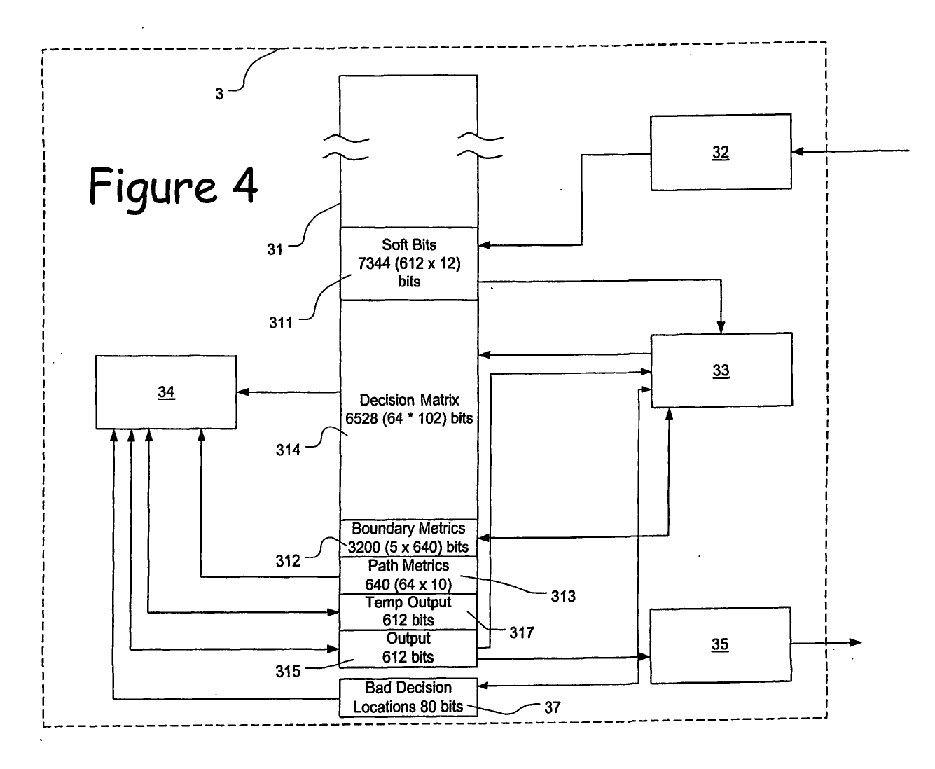

Referring to FIG. 4, the Viterbi decoder of the baseband DSP subsystem 3 includes a register unit 37 which is used to store the positions, i.e. symbol index and state, of the four worst decisions taken during path metric processing and a temporary output part 317. There are four 10-bit registers for decision metrics and four 10-bits registers for the corresponding input index values. The worst decision is that having the smallest differential between the path metrics forming the basis of the decision.

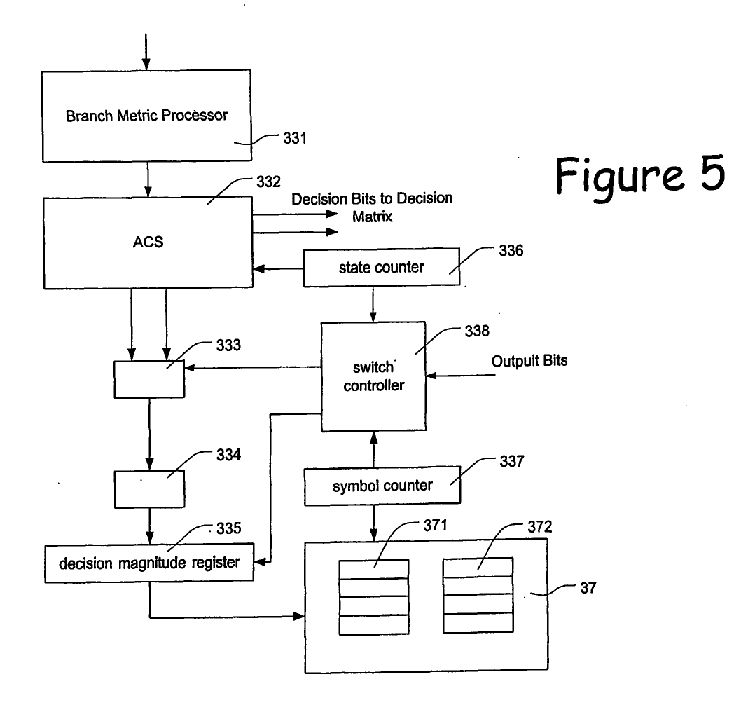

Referring to FIG. 5, the metric processing circuit 33 comprises a conventional branch metric processing circuit 331 and a substantially conventional ACS (add-compare-select) circuit 332. The ACS circuit 332 differs from conventional circuits in that it outputs the comparison results, i.e. the differences between the metrics of paths to the same state.

The outputting of the difference values relates to the identification of the four worst decision in the decision matrix. Consequently, they and the circuitry described below are not employed when the metrics of a data block are first calculated. They only come into play, if the CRC test of the initially determined output bits fails.

In the event of a CRC failure, the difference values are output to a multiplexer 333 which selectively passes one or other of the differences. The output of the multiplexer 333 is connected to an sign removing circuit 334 which outputs just the magnitude of the input difference. A decision magnitude register 335 latches the output of the sign removing circuit 334.

A state counter 336 increments for each state pair to be processed by the ACS circuit 332. A symbol counter 337 increments for each symbol to be processed by the ACS circuit 332.

A controller 338 receives previously generated outputs bits, in synchronism with the symbols being processed by the ACS circuit 332 and the outputs of the state and symbol counters. The controller 338 outputs a first signal to the multiplexer 333. The first signal is updated when one of the new states, for which the ACS circuit 332 is calculating path metrics, is on the previously determined best path. When the first control signal is updated is controls the mulitplexer 333 so that it selects the difference value that applies to the previously determined best path. A second signal is output when the first signal is updated and causes the output of the sign removing circuit 334 to be loaded into the decision magnitude register 335.

When a difference has been loaded into the decision magnitude register 335, it is compared in the bad decision location register unit 37 with any earlier values. If it is smaller than the largest difference already in the bad decision list stored in the bad decision location register unit 37, it is inserted into the list 371 in magnitude order and the largest difference is removed from the list. The symbol index for the new bad decision is also stored in a corresponding list 372 in the bad decision location register unit 37 at the expense of that for the previous largest difference.

At the start of processing, the registers in the bad decision location register unit 37 are initialised to their maximum values.

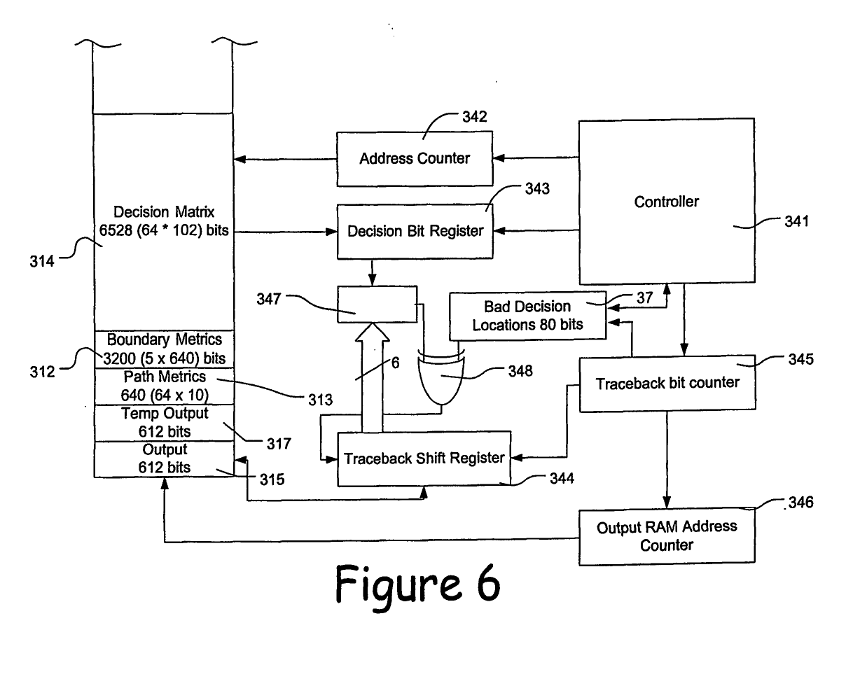

Referring to FIG. 6, the traceback circuit 34 comprises a controller 341 in the form of a state machine which provides control and synchronising signals to the other elements of the traceback circuit 34. A decision address counter 342 is controlled by the controller to generate read addresses for reading successive blocks of 64 decision bits from the decision matrix 314. These blocks of decision bits are stored temporarily in a 64-bit decision bit register 343.

The output bits are created in a traceback shift register 344 and periodically written to the output part 315 of the RAM 31. A traceback bit counter 345 is clocked by a signal from the controller 341 and outputs clock signals to the traceback shift register 344 and an output RAM address counter 346 which provides the write addresses for the writing of output bits from the traceback shift register 344.

The bad decision location register unit 37 can receive a decision selection signal from the controller 341 for selecting one of the plurality of bad decisions therein and a clock signal from the traceback bit counter 345.

A bit selection circuit 347 receives an address signal, comprising the six most significant bits in the traceback shift register 344, and the bits in the decision bit register 343 and outputs the decision bit at the position identified by the address signal. An exclusive OR gate 348 receives the outputs of the bit selection circuit 347 and the bad decision location register unit 37 and outputs its result to the data input of the traceback shift register 344.

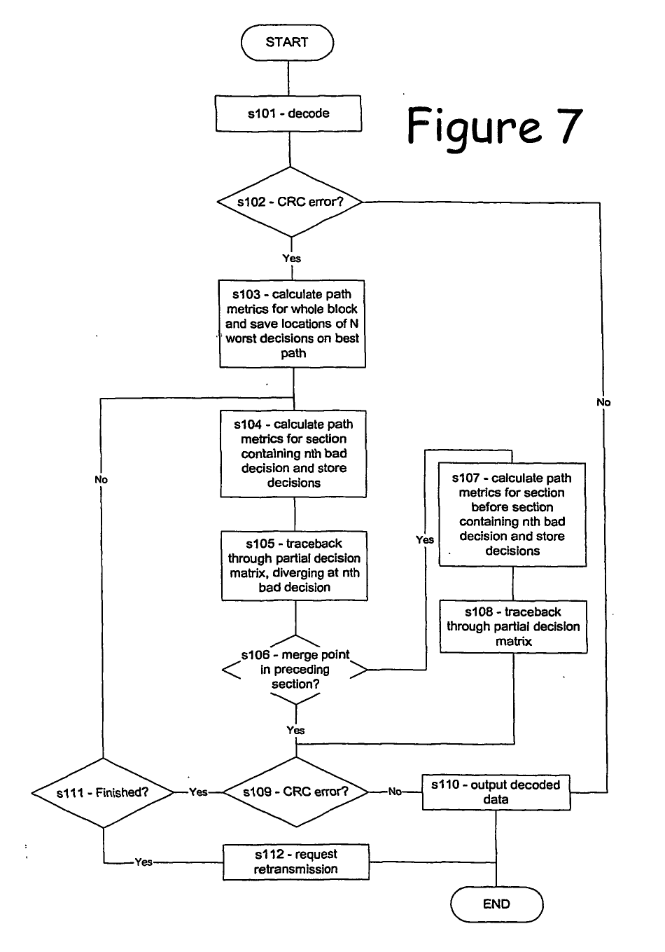

Referring to FIG. 7, the operation of the Viterbi decoder is initially as described above with reference to FIG. 3, (step s101). However, on completion of the decoding, a CRC value is calculated and compared with a CRC value in the decoded data (step s102). If there CRC values match, the decoded data is output (silo).

In the event of a CRC error (step s102), alternative paths through the lattice are tested. First, the path metrics for the whole block are calculated again by the metric processing unit 33 and the quality of the decisions on the best path, as defined by the output bits in the output part 315 of the RAM 31, is monitored (step s103) by means of the multiplexer 333, the sign removing circuit 334, the decision magnitude register 335, the controller 338 and the bad decision register unit 37. The symbol index values at which the four worst decisions occurred and the magnitudes decision metrics, i.e. the aforementioned differences, themselves are stored in the bad decision location register unit 37. The bad decisions must be more than the statistically determined merging distance from the start of the first section.

Using the boundary metrics in the boundary metric part 312 of the RAM 31, the decision matrix for the section containing the worst decision is recalculated by the metric processing unit 33 and stored in the decision matrix part 314 of the RAM 31 (step s104). The traceback unit 34 then copies the contents of the output part 315 of the RAM 31 to the temporary output part 317 and traces a path through the decision matrix (step s105). In this case, the best path is traced initially to the worst decision and then in the second best direction at the bad decision, as specified in the bad decision location register unit 37, and thereafter in the normal manner.

Referring again to FIG. 6, the controller 31 initially sets the decision address counter 332 to the top of the decision matrix 314 and sets the six most significant bits in the traceback shift register 334 to the best path state for the symbol at the end of the current section. If the current section is symbols 510 to 611, the initial value is the state which has the best metric. In other cases, the initial value comprises the 6 output bits corresponding to the first six bits of the succeeding section which are loaded from the output part 315 of the RAM 31.

The 64 decision bits form the top of the decision matrix 314 are read out and loaded into the decision bit register 333. At the same time, the current symbol position, indicated by a signal from the traceback bit counter, is compared with the symbol position of the currently selected bad decision in the bad decision location register unit 37. If there is a match a “1” is output to the exclusive OR gate 338, otherwise a “0” is output.

The bit selection circuit 337 selects one of the bits in the decision bit register according to the 6 most significant bits from the traceback shift register 334. The selected bit is input into the exclusive OR gate 338. Thus, if the bad decision symbol has been reached, the selected bit is inverted before being input into the data input of the traceback shift register 334 which is then clocked.

The decision address counter 332 is then decremented and the traceback for the next symbol is carried out. This process is repeated until all of the decisions in the decision matrix 314 have been read out.

While the above process is being performed, the contents of the traceback shift register 334, excluding the six-most significant bits, are periodically, e.g. every 64 symbols, written to the output part 315 of the RAM 31 to an address specified by the output RAM address counter 336, which is incremented after each write operation by a signal from the traceback bit counter.

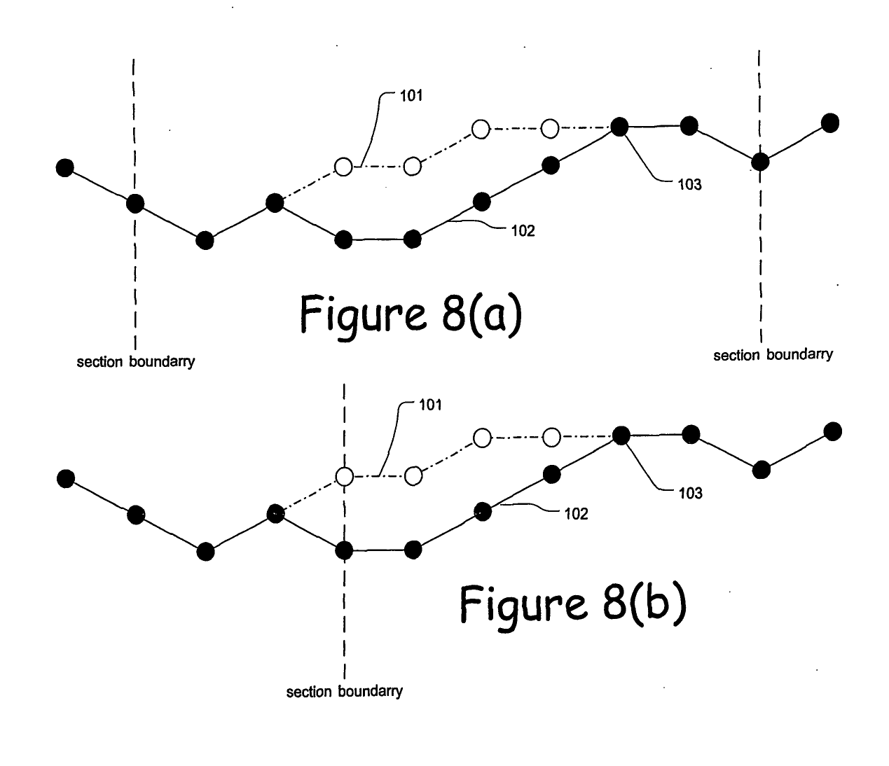

Referring also to FIG. 8(a), it can be expected that the diverging path 101 will rejoin the best path 102 within a certain number of symbols, which can be statistically determined. If, as shown in FIG. 8(a), the paths merge, or can be expected to merge, within the 102-bit section containing the bad decision 103, only one partial traceback is required. However, if the path merging distance extends across the boundary between two sections, as shown in FIG. 8(b), (step s106), the decision matrix for the preceding section is regenerated by the path metric processing unit (step s107) and the new path is traced back through the decision matrix for the preceding section (step s108).

During the tracing back (steps s105 and s108), the bits of the output, stored in the output part 315 of the RAM 31, which correspond to the retraced section(s) are updated.

When the tracing back (steps s105 and s108) has been completed, the CRC value of the updated output is checked (step s109). If the CRC value is correct, the contents of the output part 315 are output. However, if the CRC value is not correct, it is determined whether the retracing for the determined four worst decisions has been completed (step s111). If the retracing has been completed, an exception is raised causing a request for retransmission of the corrupted block to be sent (step s112). If the retracing is not finished, the traceback unit 34 restores the output from the temporary output part 317 of the RAM 31 (step s113) and the process is repeated for the next worst decision.

### Third Embodiment

The present embodiment differs from the second embodiment only in the operation of the Viterbi decoder, the general construction of the mobile phone begin as described above with reference to FIG. 1.

Referring to FIG. 7, the operation of the Viterbi decoder is initially as described above with reference to FIG. 3 (step s201). However, on completion of the decoding, a CRC value is calculated and compared with a CRC value in the decoded data (step s202). If there CRC values match, the decoded data is output (s207).

In the event of a CRC error (step s202), alternative paths through the lattice are tested. First, the path metrics for the whole block are calculated again by the metric processing unit 33 and the quality of the decisions on the best path, as defined by the output bits in the output part 315 of the RAM 31, is monitored as described above (step s203). The symbol index values at which the four worst decisions occurred are stored in the bad decision location register unit 37. The bad decisions must be more that the statistically determined merging distance from the start of the first section.

Using the boundary metrics in the boundary metric part 312 of the RAM 31, the metric processing unit 33 starts calculating the decision matrix starting from the beginning of the section preceding that containing the bad decision. The decisions are calculated until the bad decision is reached and only the decisions for the last 102 symbols are stored in the decision matrix part 314 of the RAM 31 (step s204). The traceback unit 34 then copies the contents of the output part 315 of the RAM 31 to the temporary output part 317 and traces a path through the decision matrix (step s205). In this case, traceback shift register is initialised with the output bits for the six symbols following the current worst decision and the path is traced initially in the second best direction from the bad decision, as specified in the bad decision location register unit 37, and thereafter in the normal manner. In this case, the exclusive OR gate 338 will invert the first decision bit selected from the decision matrix.

When the tracing back (step s205) has been completed, the CRC value of the updated output is checked (step s206). If the CRC value is correct, the contents of the output part 315 are output (step s207). However, if the CRC value is not correct, it is determined whether the retracing for the determined four worst decisions has been completed (step s208). If the retracing has been completed, an exception is raised causing a request for retransmission of the corrupted block to be sent (step s209). If the retracing is not finished, the traceback unit 34 restores the output from the temporary output part 317 of the RAM 31 (step s210) and the process is repeated for the next worst decision.

It will be appreciated that many modifications may be made to the embodiments described above. For example, the size of the decision matrix memory part and its relationship with the data block size will be varied as circumstances demand.

The process of searching the n next best paths could itself be iterated. For example, if the CRC test fails after the four next best paths have been tested, the second best path could be nominated as the best path and the process of finding the four worst decisions and retracing sections including these repeated.

Time could be saved by looking for the bad decisions in the same section and doing multiple modified tracebacks for a single metric processing pass.

The present invention may be embodied in hardware, software or a mixture of the two.

1. A Viterbi decoder for decoding convolution-coded data blocks, the decoder comprising a memory for storing a decision matrix and path metric processing means for populating the decision matrix in the memory with decision values on the basis of soft decision bits representing an input convolution-coded data block, characterised in that the number of elements of said memory, used for storing the decision matrix, is less than the product of the number of valid states for the input convolution-encoded data block and the number of symbols in the input convolution-encoded data block.

2. A Viterbi decoder according to claim 1, wherein said number of elements is an integer sub-multiple of said product.

3. A Viterbi decoder according to claim 1, wherein the path metric processing means is configured for storing path metric sets associated respectively with a plurality of spaced symbols in the input convolution-coded data block and performing path metric processing for distinct sections of an input convolution-encoded data block using respective ones of said stored path metric sets as a starting state.

4. A Viterbi decoder according to claim 1, including a traceback unit, wherein the path metric processing means is responsive to detection of an error in the decoded data to regenerate a partial decision matrix including a bad decision and the traceback unit is responsive to the detection of said error to modify the decoded data by tracing back a second best path through said partial decision matrix from said bad decision.

5. A Viterbi decoder according to claim 4, wherein the path metric processing means is responsive to detection of an error in the decoded data to regenerate a first partial decision matrix including a bad decision and a second partial decision matrix for symbols immediately preceding those for which the first partial decision matrix was regenerated, and the traceback unit w is responsive to the detection of said error to modify the decoded data by tracing back a second best path through said first and second partial decision matrices from said bad decision.

6. A Viterbi decoder according to claim 4, wherein said partial decision matrix covers a predetermined number of symbols preceding said bad decision.

7. A Viterbi decoding method for decoding convolution-coded data blocks, the method comprising processing path metrics on the basis of input soft decision bits, representing an input convolution-coded data block, to populate a decision matrix in a memory with decision values, characterised in that the number of elements of said memory, used for storing the decision matrix, is less than the product of the number of valid states for the input convolution-encoded data block and the number of symbols in the input convolution-encoded data block.

8. A method according to claim 7, wherein said number of elements is an integer sub-multiple of said product.

9. A method according to claim 7, including storing path metric sets, associated respectively with a plurality of spaced symbols in the input convolution-coded data block, wherein the path metric processing is performed for distinct sections of an input convolution-encoded data block using respective ones of said stored path metric sets as a starting state.

10. A method according to claim 7, including responding to the detection of an error in the decoded data to regenerate a partial decision matrix including a bad decision and modifying the decoded data by tracing back a second best path through said partial decision matrix from said bad decision.

11. A method according to claim 10, including responding to detection of an error in the decoded data by regenerating a first partial decision matrix including a bad decision and a second partial decision matrix for symbols immediately preceding those for which the first partial decision matrix was regenerated, and modifying the decoded data by tracing back a second best path through said first and second partial decision matrices from said bad decision.

12. A method according to claim 10, wherein said partial decision matrix covers a predetermined number of symbols preceding said bad decision.

13. A Viterbi decoder for decoding convolution-coded data blocks, the decoder comprising:
a decision matrix memory for storing a decision matrix;
a path metric processing unit for populating the decision matrix in the memory with decision values on the basis of soft decision bits representing an input convolution-coded data block; and
a traceback unit;
wherein the number of elements of said memory, used for storing the decision matrix, is less than the product of the number of valid states for the input convolution-encoded data block and the number of symbols in the input convolution-encoded data block.

14. A Viterbi decoder according to claim 13, wherein said number of elements is an integer sub-multiple of said product.

15. A Viterbi decoder according to claim 13, including:
a path metric memory for storing path metric sets associated respectively with a plurality of spaced symbols in the input convolution-coded data block;
wherein the path metric processing unit is configured for storing path metric sets, associated respectively with a plurality of spaced symbols in the input convolution-coded data block, in said path metric memory and perform path metric processing for distinct sections of an input convolution-encoded data block using respective path metric sets, read from said path metric memory, as the starting states.

16. A Viterbi decoder according to claim 13, including an error detector for detecting error in the decoded data, wherein the path metric processing unit is responsive to detection of an error by the error detector to regenerate a partial decision matrix including a bad decision and the traceback unit is responsive to the detection of an error by the error detector to modify the decoded data by tracing back a second best path through said partial decision matrix from said bad decision.

17. A Viterbi decoder according to claim 16, wherein the path metric processing unit is responsive to detection of an error by the error detector to regenerate a first partial decision matrix including a bad decision and a second partial decision matrix for symbols immediately preceding those for which the first partial decision matrix was regenerated, and the traceback unit is responsive to the detection of said error by the error detector to modify the decoded data by tracing back a second best path through said first and second partial decision matrices from said bad decision.

18. A Viterbi decoder according to claim 16, wherein said partial decision matrix covers a predetermined number of symbols preceding said bad decision.

19. A Viterbi decoding method for decoding convolution-coded data blocks, the method comprising:
processing path metrics on the basis of input soft decision bits, representing an input convolution-coded data block, to populate a decision matrix in a memory with decision values,
wherein the number of elements of said memory, used for storing the decision matrix, is less than the product of the number of valid states for the input convolution-encoded data block and the number of symbols in the input convolution-encoded data block.

20. A method according to claim 19, wherein said number of elements is an integer sub-multiple of said product.

21. A method according to claim 19, including storing path metric sets, associated respectively with a plurality of spaced symbols in the input convolution-coded data block, wherein the path metric processing is performed for distinct sections of an input convolution-encoded data block using respective ones of said stored path metric sets as a starting state.

22. A method according to claim 19, including responding to the detection of an error in the decoded data to regenerate a partial decision matrix including a bad decision and modifying the decoded data by tracing back a second best path through said partial decision matrix from said bad decision.

23. A method according to claim 22, including responding to detection of an error in the decoded data by regenerating a first partial decision matrix including a bad decision and a second partial decision matrix for symbols immediately preceding those for which the first partial decision matrix was regenerated, and modifying the decoded data by tracing back a second best path through said first and second partial decision matrices from said bad decision.

24. A method according to claim 22, wherein said partial decision matrix covers a predetermined number of symbols preceding said bad decision.

25. A communication device including a Viterbi decoder according to claim 1.
